(19) United States
(12) Patent Application Publication
(10) Pub. No.: US 2026/0082547 A1
(43) Pub. Date: Mar. 19, 2026

(54) SEMICONDUCTOR DEVICE AND SEMICONDUCTOR MEMORY DEVICE

(71) Applicant: Kioxia Corporation, Tokyo (JP)

(72) Inventors: Yuya MATSUZAWA, Yokkaichi Mie (JP); Kotaro NODA, Yokkaichi Mie (JP)

(21) Appl. No.: 19/066,051

(22) Filed: Feb. 27, 2025

(30) Foreign Application Priority Data
Sep. 19, 2024 (JP) 2024-162719

(51) Int. Cl. H10B 12/00

(52) U.S. Cl. CPC H10B 12/33; H10B 12/05

(57) ABSTRACT

A semiconductor device includes gate electrodes that extend in a first direction and are separated from each other in a second direction intersecting the first direction, bit electrodes that extend in the second direction above the gate electrodes and are separated from each other in the first direction, oxide semiconductors that extend along a third direction intersecting the first and second directions, penetrate the gate electrodes, and are electrically connected to the gate electrodes and the bit electrodes, and gate insulating films each surrounding a corresponding one of the oxide semiconductors. Within an intersection region in which one of the gate electrodes overlaps one of the bit electrodes in the third direction, said one of the gate electrodes opposes one of the oxide semiconductors across the gate insulating film. A cross-section of each of the oxide semiconductors taken along the first and second directions has an oval shape.

### CROSS-REFERENCE TO RELATED APPLICATION(S)

This application is based upon and claims the benefit of priority from Japanese Patent Application No. 2024-162719, filed Sep. 19, 2024, the entire contents of which are incorporated herein by reference.

### FIELD

Embodiments described herein relate generally to a semiconductor device and a semiconductor memory device.

### BACKGROUND

Among semiconductor elements, there are those that are formed of an oxide semiconductor.

### BRIEF DESCRIPTION OF THE DRAWINGS

FIG. 1 is a circuit drawing illustrating a circuit configuration of a memory cell array according to a first embodiment.

FIG. 2 is a sectional schematic view illustrating a structure of a semiconductor memory device according to the first embodiment, and is a sectional view parallel to a ZX plane.

FIG. 3 is a cross-section that is parallel to the ZX plane, and is a detailed sectional view of a semiconductor device according to the first embodiment when seen in the cross-section in an oxide semiconductor layer.

FIG. 4 is a cross-section that is parallel to the YZ plane, and is a detailed sectional view of the semiconductor device when seen in the cross-section in the oxide semiconductor layer.

FIG. 5 is a sectional view along a section line V-V shown in FIGS. 3 and 4.

FIG. 6 is a sectional view parallel to the ZX plane showing a process of manufacturing the semiconductor device according to the first embodiment.

FIG. 7 is a sectional view parallel to the ZX plane showing the process of manufacturing the semiconductor device according to the first embodiment.

FIG. 8 is a sectional view parallel to the ZX plane showing the process of manufacturing the semiconductor device according to the first embodiment.

FIG. 9 is a sectional view parallel to the ZX plane showing the process of manufacturing the semiconductor device according to the first embodiment.

FIG. 10 is a sectional view parallel to the ZX plane showing the process of manufacturing the semiconductor device according to the first embodiment.

FIG. 11 is a sectional view parallel to the ZX plane showing the process of manufacturing the semiconductor device according to the first embodiment.

FIG. 12 is a sectional view parallel to the ZX plane showing the process of manufacturing the semiconductor device according to the first embodiment.

FIG. 13 is a sectional view parallel to the ZX plane showing the process of manufacturing the semiconductor device according to the first embodiment.

FIG. 14 is a sectional view parallel to the ZX plane showing the process of manufacturing the semiconductor device according to the first embodiment.

FIG. 15 is a sectional view parallel to the ZX plane showing the process of manufacturing the semiconductor device according to the first embodiment.

FIG. 16 is a drawing showing a cross-section of a semiconductor device according to a second embodiment along the section line V-V shown in FIGS. 3 and 4.

FIG. 17 is a drawing showing a cross-section of a semiconductor device according to a third embodiment along the section line V-V shown in FIGS. 3 and 4.

FIG. 18 is a cross-section that is parallel to the ZX plane, and is a detailed sectional view of a semiconductor device according to a fourth embodiment when seen in the cross-section in the oxide semiconductor layer.

FIG. 19 is a cross-section that is parallel to the YZ plane, and is a detailed sectional view of the semiconductor device according to the fourth embodiment when seen in the cross-section in the oxide semiconductor layer.

FIG. 20 is a sectional view along the section line XX-XX shown in FIGS. 18 and 19.

FIG. 21 is a sectional view parallel to the ZX plane showing a process of manufacturing the semiconductor device according to the fourth embodiment.

FIG. 22 is a sectional view parallel to the ZX plane showing the process of manufacturing the semiconductor device according to the fourth embodiment.

FIG. 23 is a sectional view parallel to the ZX plane showing the process of manufacturing the semiconductor device according to the fourth embodiment.

FIG. 24 is a sectional view parallel to the ZX plane showing the process of manufacturing the semiconductor device according to the fourth embodiment.

FIG. 25 is a sectional view parallel to the ZX plane showing the process of manufacturing the semiconductor device according to the fourth embodiment.

FIG. 26 is a sectional view parallel to the ZX plane showing the process of manufacturing the semiconductor device according to the fourth embodiment.

FIG. 27 is a sectional view parallel to the ZX plane showing the process of manufacturing the semiconductor device according to the fourth embodiment.

FIG. 28 is a sectional view parallel to the ZX plane showing the process of manufacturing the semiconductor device according to the fourth embodiment.

FIG. 29 is a drawing showing a cross-section of a semiconductor device according to a fifth embodiment along the section line XX-XX shown in FIGS. 18 and 19.

FIG. 30 is a drawing showing a cross-section of a semiconductor device according to a sixth embodiment along the section line XX-XX shown in FIGS. 18 and 19.

### DETAILED DESCRIPTION

There is a demand for a technology capable of improving the quality of semiconductor devices by appropriately connecting a semiconductor layer containing oxygen to an electrode.

Embodiments provide a semiconductor device and a semiconductor memory device such that a high-quality semiconductor device can be manufactured.

In general, according to one embodiment, a semiconductor device, comprises a plurality of gate electrodes that extend in a first direction and are separated from each other in a second direction intersecting the first direction; a plurality of bit electrodes that extend in the second direction above the gate electrodes and are separated from each other in the first direction; a plurality of oxide semiconductors that extend along a third direction intersecting the first and second directions, penetrate the gate electrodes, and are electrically connected to the gate electrodes and the bit electrodes; and a plurality of gate insulating films each surrounding a corresponding one of the oxide semiconductors. Within an intersection region in which one of the gate electrodes overlaps one of the bit electrodes in the third direction, said one of the gate electrodes opposes one of the oxide semiconductors across the gate insulating film. A cross-section of each of the oxide semiconductors along the first and second directions has an oval shape.

Hereafter, embodiments will be described while referring to the attached drawings. In order to facilitate understanding of the description, identical reference signs will be allotted, as far as possible, to identical components in the drawings, and redundant descriptions will be omitted.

### First Embodiment

A configuration of a semiconductor memory device 101 according to a first embodiment will be described. An X axis, a Y axis, and a Z axis may be shown in the drawings. The X axis, the Y axis, and the Z axis form right-handed three-dimensional Cartesian coordinates. Hereafter, an X axis arrow direction may be called an X axis +direction, and a direction opposite to that of the arrow an X axis −direction, with the same applying to the other axes. The Z axis +direction and the Z axis −direction may be called “upward” and “downward” respectively. Also, planes perpendicular to the X axis, the Y axis, and the Z axis may be called a YZ plane, a ZX plane, and an XY plane respectively. Also, the Z axis direction may be called an “up-down direction”. “Upward”, “downward”, and “up-down direction” are merely terms indicating a relative positional relationship in the drawings, and are not terms that specify an orientation having a vertical direction as a reference.

In the present specification, “connection” includes not only a physical connection but also an electrical connection, and unless specifically stated otherwise, includes not only a direct connection but also an indirect connection.

In the present specification, unless specifically stated otherwise, “formed upward” includes not only a case of being formed in contact upward, but also a case of being formed upward across another object. The same applies to a case of being “formed downward”, or the like.

The semiconductor memory device 101 according to the first embodiment is an oxide semiconductor random access memory (OS-RAM), and includes a memory cell array.

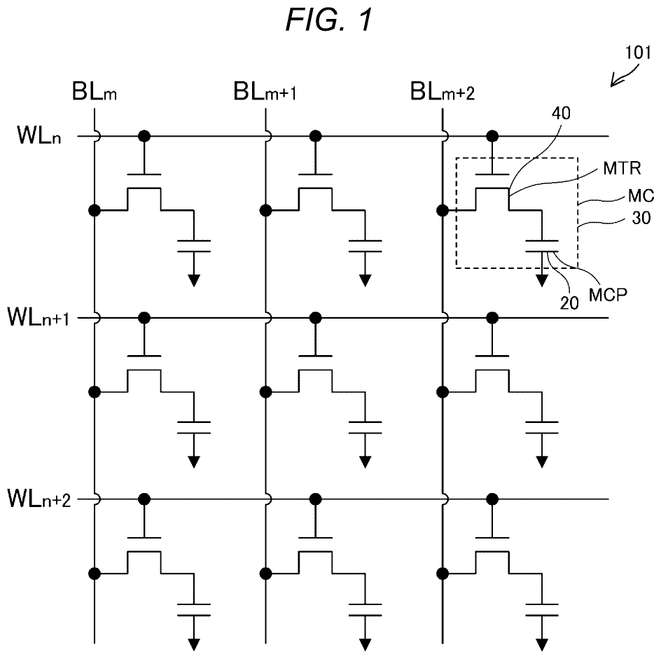

As shown in FIG. 1, the memory cell array includes a multiple of memory cells MC, a multiple of word lines WL, and a multiple of bit lines BL.

In FIG. 1, a word line WLn, a word line WLn+1, and a word line WLn+2 are shown as examples of the multiple of word lines WL (herein, n is a positive integer). Also, in FIG. 1, a bit line BLm, a bit line BLm+1, and a bit line BLm+2 are shown as examples of the multiple of bit lines BL (herein, m is a positive integer). The quantity of the multiple of memory cells MC is not limited to the quantity shown in FIG. 1.

The multiple of memory cells MC form the memory cell array by being arrayed in, for example, a matrix form. The memory cell MC includes a memory transistor MTR, which is a field-effect transistor (FET), and a memory capacitor MCP.

One series of memory cells MC provided in a row direction is connected to the word line WL (for example, the word line WLn) corresponding to the row to which the series of memory cells MC belongs (for example, the nth row). One series of memory cells MC provided in a column direction is connected to the bit line BL (for example, the bit line BLm+2) corresponding to the column to which the series of memory cells MC belongs (for example, the m+2th column).

Specifically, a gate of the memory transistor MTR in the memory cell MC is connected to the word line WL corresponding to the row to which the memory cell MC belongs. Either a source or a drain of the memory transistor MTR is connected to the bit line BL corresponding to the column to which the memory cell MC belongs.

One electrode of the memory capacitor MCP in the memory cell MC is connected to the other of the source or the drain of the memory transistor MTR in the memory cell MC. The other electrode of the memory cell MC is connected to a power supply line (not shown) that supplies a specific voltage.

Using a switching of the memory transistor MTR based on a voltage of the corresponding word line WL, the memory cell MC is able to store data owing to an accumulation of a charge in the memory capacitor MCP caused by a current flowing through the corresponding bit line BL.

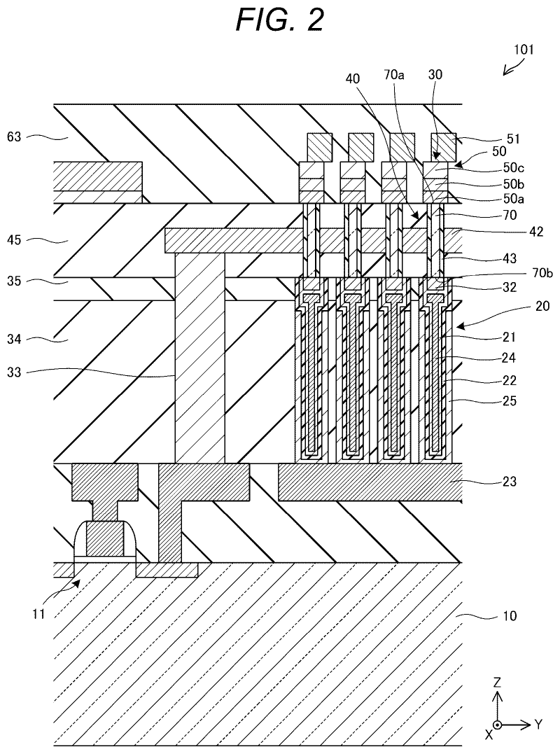

As shown in FIG. 2, the semiconductor memory device 101 includes a semiconductor substrate 10, a circuit 11 (e.g., a semiconductor circuit), a capacitor 20, a semiconductor device 30, a conductor 33, and insulating layers 34, 35, and 63.

The capacitor 20 includes an insulating film 22 (or a dielectric film), a conductor 23, a capacitor electrode 24, and a capacitor electrode 25.

The semiconductor device 30 includes a field-effect transistor 40 as a semiconductor element, an upper electrode 50 provided above the field-effect transistor 40, a lower electrode 32 provided below the field-effect transistor 40, and a conductive layer 51 that corresponds to a bit electrode in one embodiment.

The field-effect transistor 40 includes an oxide semiconductor layer 70, a gate insulating film 43, a conductive layer 42 that corresponds to a gate electrode in one embodiment, and an insulating layer 45. The field-effect transistor 40 corresponds to the memory transistor MTR of the memory cell MC (refer to FIG. 1).

The oxide semiconductor layer 70 is formed in the insulating layer 45, and has an upper end 70a and a lower end 70b. The oxide semiconductor layer 70 is a columnar body that extends in the up-down direction. The oxide semiconductor layer 70 forms a channel of the field effect transistor 40. The oxide semiconductor layer 70 has an amorphous structure.

The oxide semiconductor layer 70 is a semiconductor such that an oxygen vacancy is a donor. The oxide semiconductor layer 70 includes at least one of indium (In), gallium (Ga), zinc (Zn), tin (Sn), aluminum (Al), iridium (Ir), ruthenium (Ru), and titanium (Ti), and includes oxygen.

In the present embodiment, the oxide semiconductor layer 70 includes indium, zinc, and gallium as metallic elements. Specifically, the oxide semiconductor layer 70 is an oxide of indium, gallium, and zinc, that is, an IGZO (InGaZnO). The oxide semiconductor layer 70 may also be another kind of oxide semiconductor.

The field-effect transistor 40 is a so-called vertical transistor having a channel that extends in the Z axis direction (i.e., the up-down direction), which is approximately vertical to the surface of the semiconductor substrate 10.

The conductive layer 42 opposes the oxide semiconductor layer 70 across the gate insulating film 43. Specifically, the conductive layer 42 functions as a gate electrode of the field effect transistor 40, and encloses the oxide semiconductor layer 70 across the gate insulating film 43 between the upper end 70a and the lower end 70b of the oxide semiconductor layer 70. The conductive layer 42 includes, for example, tungsten (W).

The gate insulating film 43 includes a silicon nitride film (Si3N4) containing, for example, silicon and nitrogen. The gate insulating film 43 is formed to cover a whole periphery of a side face of the oxide semiconductor layer 70.

The upper electrode 50 is formed above the oxide semiconductor layer 70, and is connected to the upper end 70a of the oxide semiconductor layer 70. The upper electrode 50 includes a metal oxide layer 50a, a barrier metal layer 50b, and a metal film 50c.

The metal oxide layer 50a is connected to the upper end 70a of the oxide semiconductor layer 70. In the present embodiment, the metal oxide layer 50a is in contact with the upper end 70a of the oxide semiconductor layer 70. The metal oxide layer 50a includes an oxide conductive material. Specifically, the oxide conductive material is an oxide conductive material including indium and tin as metallic elements. More specifically, the oxide conductive material is indium-tin-oxide (ITO).

The metal film 50c is provided above the metal oxide layer 50a, and includes tungsten. The barrier metal layer 50b is formed between the metal oxide layer 50a and the metal film 50c. The barrier metal layer 50b includes, for example, titanium and nitrogen. In the present embodiment, the barrier metal layer 50b is formed of titanium nitride (TiN).

The conductive layer 51 is connected to the upper end 70a of the oxide semiconductor layer 70 via the upper electrode 50. The conductive layer 51 includes, for

### Example, Tungsten (W).

The lower electrode 32 is connected to the lower end 70b of the oxide semiconductor layer 70. The lower electrode 32 is formed of a metal oxide including an oxide conductive material. Specifically, the lower electrode 32 includes, for example, indium and tin as metallic elements. In the present embodiment, the lower electrode 32 is formed of indium-tin-oxide (ITO).

The lower electrode 32 and the metal oxide layer 50a, not being limited to ITO, may include at least any one element among indium, tin, zinc, cadmium, gold, silver, platinum, lead, copper, nickel, tungsten, and iron.

The circuit 11 is a peripheral circuit of a decoder for selecting a predetermined memory cell MC among the multiple of memory cells MC, that is, the capacitors 20 and the field-effect transistors 40, of the semiconductor memory device 101, a sense amplifier connected to the bit line BL, a register configured with an SRAM, and the like. The circuit 11 may include a CMOS circuit having field-effect transistors, which are a p-channel field-effect transistor (Pch-FET) and an n-channel field-effect transistor (Nch-FET), formed using a CMOS process.

A field-effect transistor of the circuit 11 can be formed using the semiconductor substrate 10, which is a single crystal silicon substrate or the like. The Pch-FET and the Nch-FET are so-called lateral field-effect transistors that have a channel region, a source region, and a drain region in the semiconductor substrate 10, and have a channel for causing a carrier to flow in the X axis direction and the Y axis direction, which are approximately parallel to a surface of the semiconductor substrate 10, in a region near the surface of the semiconductor substrate 10. The semiconductor substrate 10 may have p-type or n-type conductivity. For the sake of convenience, FIG. 2 shows one example of a field-effect transistor of the circuit 11.

The capacitor 20 is the memory capacitor MCP in the memory cell MC (refer to FIG. 1). Although four capacitors 20 are shown in FIG. 2, the quantity of capacitors 20 is not limited to four.

In the present embodiment, the capacitor 20 is provided above the semiconductor substrate 10. The capacitor electrode 24 of the capacitor 20 is connected to the oxide semiconductor layer 70 via the conductor 21 and the lower electrode 32. The capacitor electrode 25 opposes the capacitor electrode 24. The insulating film 22 is provided between the capacitor electrode 24 and the capacitor electrode 25.

The capacitor 20 is a three-dimensional capacitor, such as a pillar-type capacitor. Another capacitor that includes a configuration such that a charge can be accumulated may be employed as a capacitor according to the present embodiment.

Specifically, the capacitor electrode 24 is positioned below the lower electrode 32. The capacitor electrode 24 has an upper end that opposes a lower end face of the lower electrode 32 across the conductor 21, and has a columnar form that extends downward from the upper end. The conductor 21 is formed to cover the lower electrode 32 and the capacitor electrode 24. The insulating film 22 is formed to cover the conductor 21. The capacitor electrode 25 has a lower end that encloses a lower portion of the insulating film 22 and is in contact with an upper end face of the conductor 23.

The capacitor electrode 24 may include a material, such as SiGe, containing silicon and germanium. The insulating film 22 may include a material, such as ZrAlO, containing zirconium, aluminum, and oxygen. The conductor 21 may include a material, such as titanium nitride, containing nitrogen and titanium. The conductor 23 and the capacitor electrode 25 may include materials such as tungsten and titanium nitride.

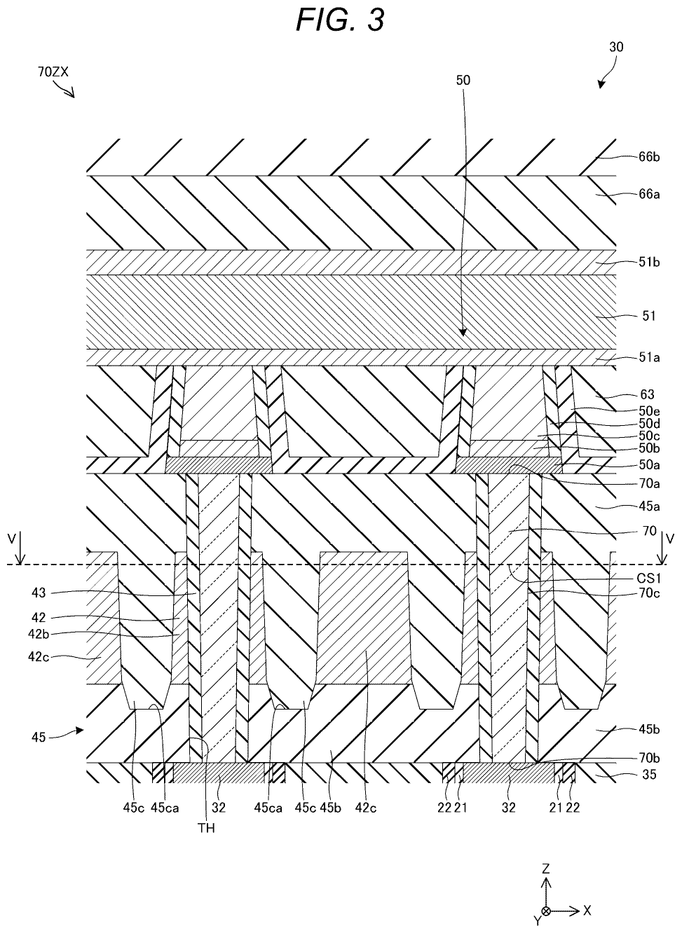

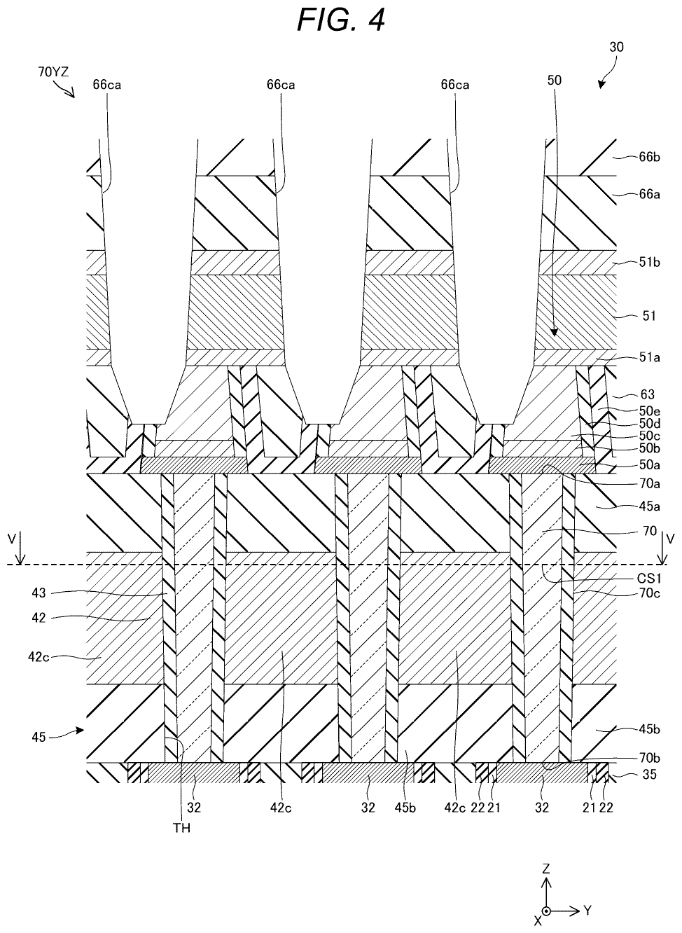

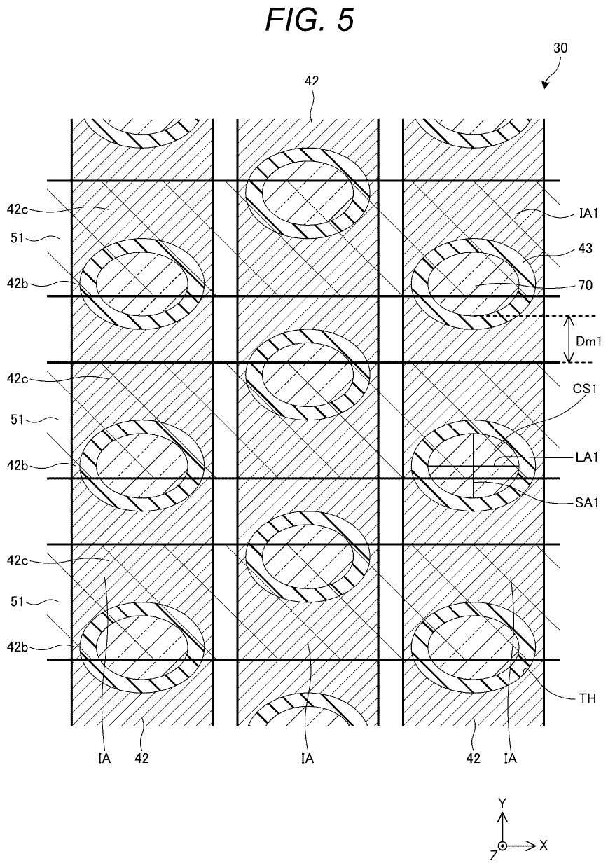

FIG. 3 is a cross-section 70ZX that is parallel to the ZX plane, and is a detailed sectional view of the semiconductor device 30 when seen in the cross-section 70ZX in the oxide semiconductor layer 70. FIG. 4 is a cross-section 70YZ that is parallel to the YZ plane, and is a detailed sectional view of the semiconductor device 30 when seen in the cross-section 70YZ in the oxide semiconductor layer 70. FIG. 5 is a sectional view along a section line V-V shown in FIGS. 3 and 4. In FIG. 5, the conductive layer 51 when seen from above is shown superimposed in order to describe dispositions of the conductive layer 42, the conductive layer 51, and the oxide semiconductor layer 70.

As shown in FIGS. 3 to 5, the conductive layer 42 extends in the Y axis direction, which intersects the up-down direction. A multiple of the conductive layer 42 are provided. The multiple of conductive layers 42 are provided repeatedly in the X axis direction.

The multiple of conductive layers 42 are separated from each other in the X axis direction. Specifically, a groove portion 45ca that divides the conductive layer 42 and extends in the Y axis direction is formed in the conductive layer 42 and the insulating film 45b. The groove portion 45ca is filled with an insulating film 45c. The insulating film 45c includes, for example, silicon and oxygen. That is, two neighboring conductive layers 42 are separated by the insulating film 45c. The conductive layer 42 corresponds to the word line WL (refer to FIG. 1).

The conductive layer 42 encloses each of a multiple of the oxide semiconductor layer 70 provided in the Y axis direction across a multiple of the gate insulating film 43.

Specifically, the conductive layer 42 includes a multiple of enclosing portions 42b, which enclose each of the multiple of oxide semiconductor layers 70 across the gate insulating film 43, and at least one linking portion 42c that links two enclosing portions 42b. In the present embodiment, a width in the X direction of the conductive layer 42 is approximately constant.

The conductive layer 51 extends in the X axis direction above the conductive layer 42. A multiple of the conductive layer 51 are provided. The multiple of conductive layers 51 are provided repeatedly in the Y axis direction.

The multiple of conductive layers 51 are separated from each other in the Y axis direction. Specifically, a groove portion 66ca that divides two neighboring conductive layers 51 and extends in the X axis direction is formed between the two conductive layers 51. For example, an insulating layer and an air gap are provided in the groove portion 66ca. That is, two neighboring conductive layers 51 are separated by the groove portion 66ca. The conductive layer 51 corresponds to the bit line BL (refer to FIG. 1). In the present embodiment, a width in the Y direction of the conductive layer 51 is approximately constant.

When the conductive layer 42 and the conductive layer 51 are seen in the up-down direction, a multiple of regions in which the conductive layer 42 and the conductive layer 51 intersect (hereafter also referred to as “the intersection region IA”) exist (refer to FIG. 5).

The oxide semiconductor layer 70 is provided in each intersection region IA. That is, the multiple of oxide semiconductor layers 70 are arrayed two-dimensionally. Specifically, one portion of the multiple of oxide semiconductor layers 70 are provided repeatedly in the Y axis direction. Also, one portion of the multiple of oxide semiconductor layers 70 are provided repeatedly in the X axis +direction.

Specifically, when the conductive layer 42 and the conductive layer 51 are seen in the up-down direction, the conductive layer 42 passing through an intersection region IA1, which is one of the multiple of intersection regions IA, opposes the oxide semiconductor layer 70 corresponding to the intersection region IA1 across the gate insulating film 43. Herein, the oxide semiconductor layer 70 corresponding to the intersection region IA1 is, for example, the oxide semiconductor layer 70 coinciding with the intersection region IA1 when seen in the up-down direction.

In the present embodiment, the conductive layer 42 passing through the intersection region IA1 when seen in the up-down direction encloses the oxide semiconductor layer 70 corresponding to the intersection region IA1 across the gate insulating film 43. In other words, the oxide semiconductor layer 70 corresponding to the intersection region IA1 penetrates the conductive layer 42 passing through the intersection region IA1 when seen in the up-down direction.

Also, when the conductive layer 42 and the conductive layer 51 are seen in the up-down direction, the conductive layer 51 passing through the intersection region IA1 is connected to the oxide semiconductor layer 70 corresponding to the intersection region IA1 via the upper electrode 50.

Also, when two oxide semiconductor layers 70 neighboring in the X axis direction are seen in the up-down direction, one oxide semiconductor layer 70 protrudes to a Y axis direction+side from the conductive layer 51. Further, the other oxide semiconductor layer 70 protrudes to a Y axis direction-side from the conductive layer 51.

A cross-section CS1 vertical to the up-down direction of the oxide semiconductor layer 70 has an oval form. Herein, an oval form is a form such that a perfect circle is squashed, such as an elliptical form, an oblong form, or an egg-form. An oval form may also be a form such that corners of a rectangle are rounded.

A length of a major axis LA1 of the cross-section CS1 is 1.1 times or more greater than a length of a minor axis SA1 of the cross-section CS1. Also, the major axis LA1 and the minor axis SA1 follow the X axis direction and the Y axis direction respectively. In the present embodiment, the major axis LA1 and the minor axis SA1 are approximately parallel to the X axis and the Y axis respectively.

The cross-section CS1 is positioned in an opposing portion 70c of the oxide semiconductor layer 70 and the conductive layer 42. A form of a cross-section in a first connection portion in which the oxide semiconductor layer 70 and the upper electrode 50 are connected, that is, the upper end 70a, and a form of a cross-section in a second connection portion in which the oxide semiconductor layer 70 and the lower electrode 32 are connected, that is, the lower end 70b, are the same kind of oval form as that of the cross-section CS1.

### Advantages

Since the major axis LA1 of the cross-section CS1 follows the width direction of the conductive layer 42, that is, the X axis direction, as heretofore described, an amount of protrusion of the oxide semiconductor layer 70 from the conductive layer 51 can be reduced when the oxide semiconductor layer 70 is seen in the up-down direction. Specifically, a distance Dm1 between the oxide semiconductor layer 70 protruding from the conductive layer 51 and the conductive layer 51 on a side on which there is no protrusion can be secured between two neighboring conductive layers 51 when the oxide semiconductor layer 70 is seen in the up-down direction. Because of this, an electrical short-circuiting of two neighboring conductive layers 51 via the upper electrode 50 due to production variation can be restricted. Also, as an area of contact between the oxide semiconductor layer 70 and the upper electrode 50 or the lower electrode 32 can be increased in comparison with when the form of the cross-section CS1 is a perfect circle, electrical resistance between the oxide semiconductor layer 70 and the upper electrode 50 or the lower electrode 32 can be reduced.

### Semiconductor Device 30 Manufacturing Method

Hereafter, a method of manufacturing the semiconductor device 30 according to the first embodiment will be described.

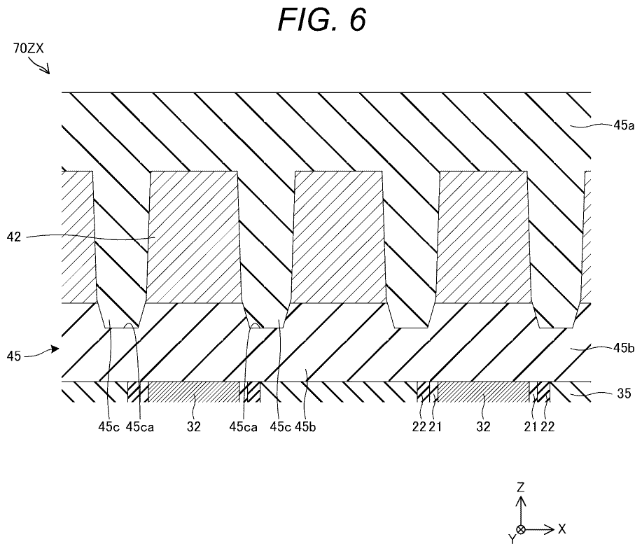

Firstly, as shown in FIG. 6, the insulating film 45b, the conductive layer 42, and insulating films 45c and 45a are stacked above the lower electrode 32 and the insulating layer 35. The insulating films 45a and 45b extend approximately parallel to the XY plane. The conductive layer 42 and the insulating film 45c are columnar bodies extending in the Y axis direction.

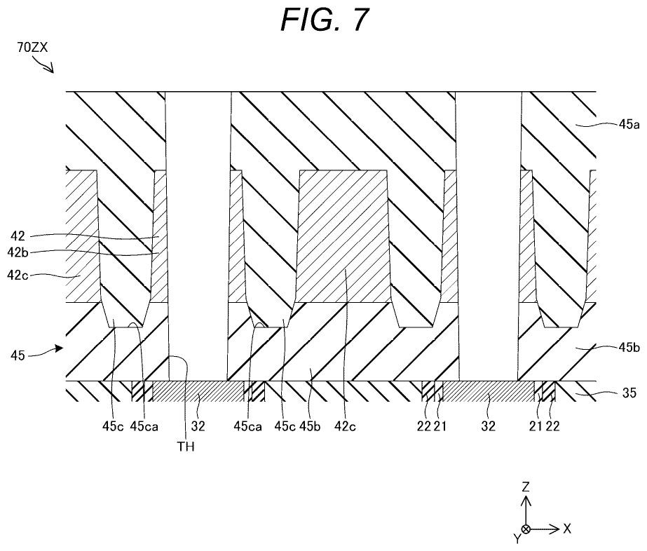

Next, as shown in FIG. 7, a transistor hole TH is formed in the insulating film 45a, the conductive layer 42, and the insulating film 45b in such a way that the lower electrode 32 is exposed, after which the transistor hole TH is cleaned. The transistor hole TH extends approximately parallel to the Z axis. The lower electrode 32 is exposed in a bottom portion of the transistor hole TH. A cross-section vertical to the up-down direction of the transistor hole TH has an oval form.

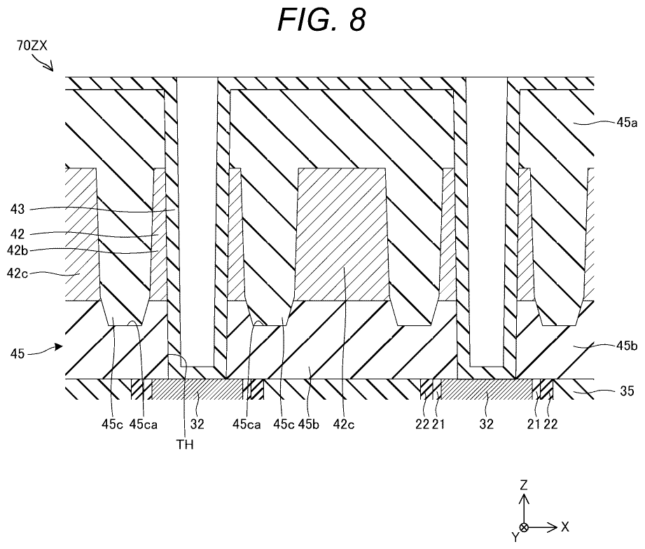

Next, as shown in FIG. 8, the gate insulating film 43 is formed to cover an upper face of the insulating film 45a and an interior of the transistor hole TH.

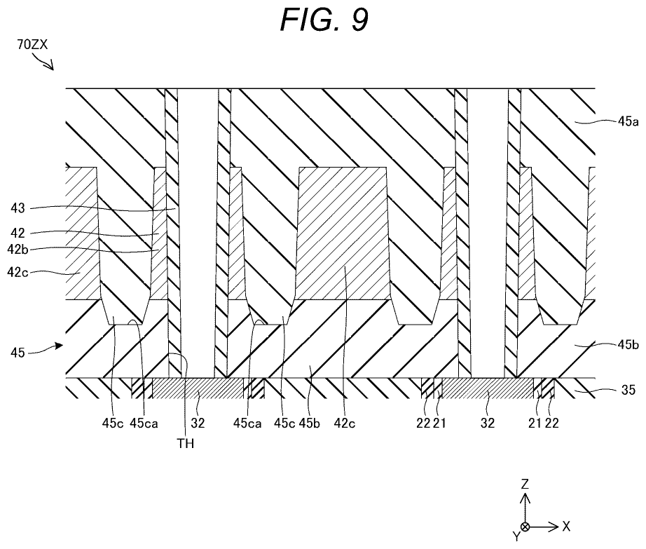

Next, as shown in FIG. 9, one portion of the gate insulating film 43 is etched using reactive ion etching. By so doing, the lower electrode 32 is exposed in the bottom portion of the transistor hole TH.

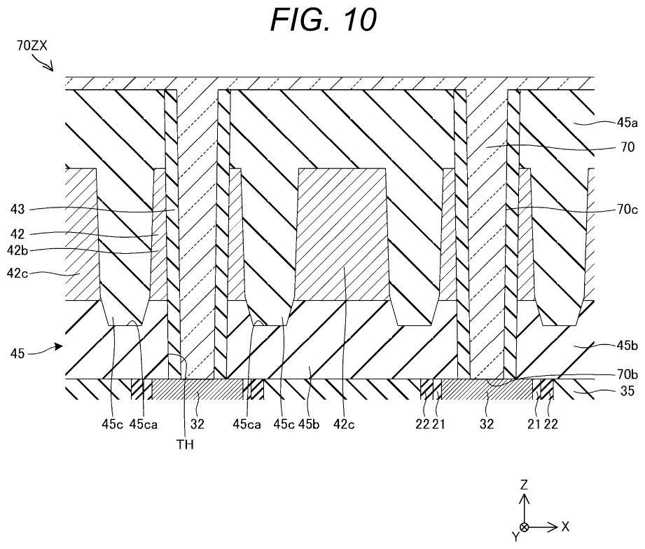

Next, as shown in FIG. 10, the oxide semiconductor layer 70 is formed on the upper face of the insulating film 45a and in the transistor hole TH. The oxide semiconductor layer 70 is in contact with an upper face of the lower electrode 32 exposed in the bottom portion of the transistor hole TH. Because of this, the transistor hole TH is filled with the oxide semiconductor layer 70.

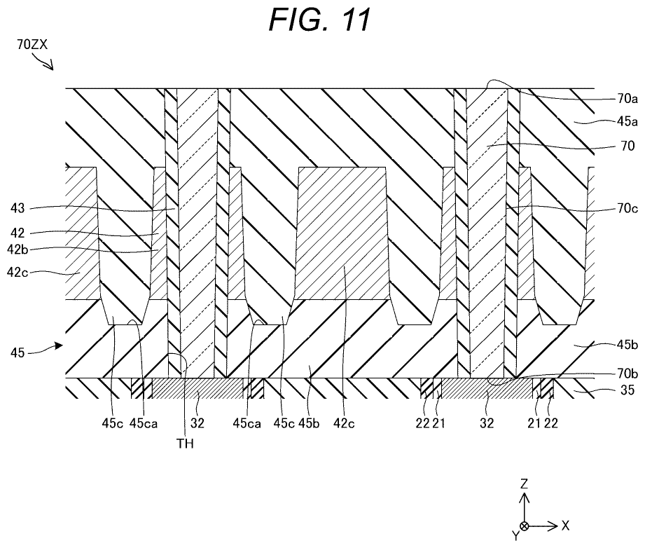

Next, as shown in FIG. 11, one portion of the oxide semiconductor layer 70 is removed, whereby an upper face of the insulating film 45a is exposed. At this time, a position in the Z axis direction of a face of the upper end 70a of the oxide semiconductor layer 70 is aligned with the upper face of the insulating film 45a.

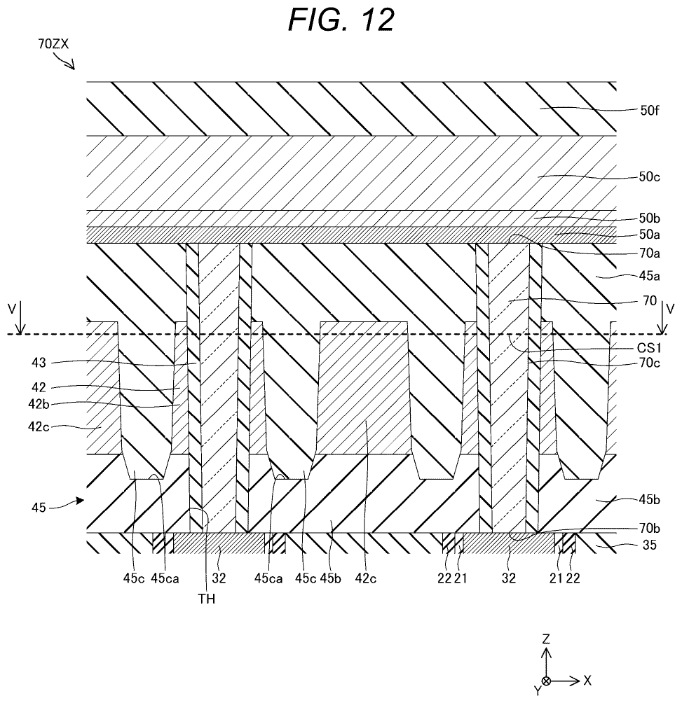

Next, as shown in FIG. 12, the metal oxide layer 50a, the barrier metal layer 50b, and the metal film 50c are formed from down to up above the insulating film 45a and the oxide semiconductor layer 70. Further, a landing pad hard mask (LPHM) film 50f including, for example, an oxide of silicon is formed above the metal film 50c.

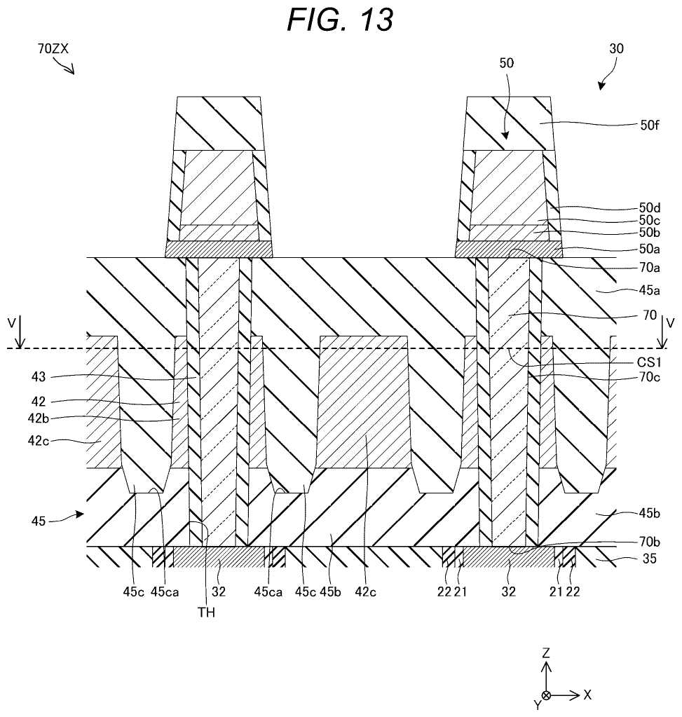

Next, as shown in FIG. 13, a mask is formed by a film formation, a resist application, exposure, development, detachment, and the like being carried out on an upper face of the LPHM film 50f using a lithographic method, after which the upper electrode 50, which functions as a landing pad, is formed by etching. The upper electrode 50 includes a barrier metal layer 51a, the barrier metal layer 50b, the metal film 50c, and an insulating film 50d. The insulating film 50d covers peripheries of the barrier metal layer 50b and the metal film 50c. The insulating film 50d is formed using, for example, an atomic layer deposition.

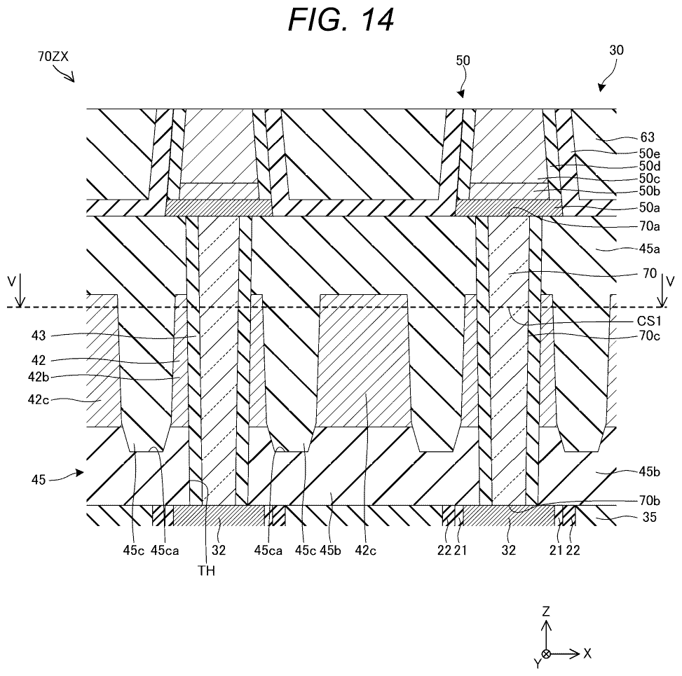

Next, as shown in FIG. 14, an LP liner film 50e including, for example, an oxide of silicon is formed on the upper face of the insulating film 45a and on the upper electrode 50. An insulating layer 63 that fills a gap caused by the LP liner film 50e is formed above the LP liner film 50e. The insulating layer 63 includes, for example, an oxide of silicon. Further, a chemical mechanical polishing is carried out on a face exposed upward.

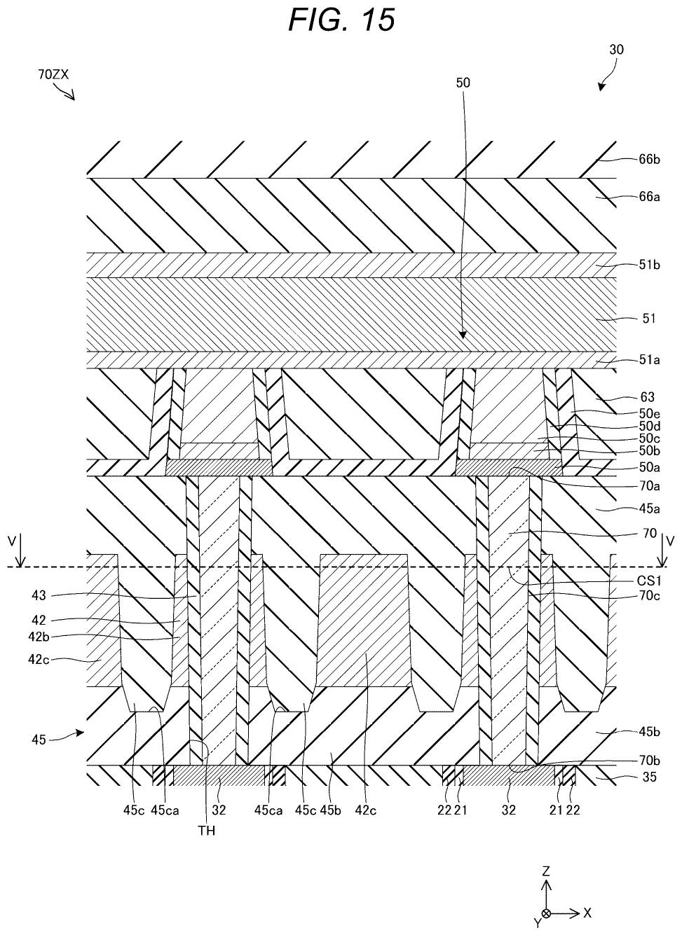

Next, as shown in FIG. 15, the barrier metal layer 51a, the conductive layer 51, and a barrier metal layer 51b are formed from down to up on the face exposed upward. The barrier metal layers 51a and 51b include, for example, titanium nitride. The conductive layer 51 includes, for example, tungsten.

Further, bit line hard mask (BLHM) films 66a and 66b are formed from down to up on an upper face of the barrier metal layer 51b. The BLHM films 66a and 66b include, for example, a nitride of silicon and an oxide of silicon respectively.

Next, as shown in FIGS. 3 and 4, a mask is formed by a film formation, a resist application, exposure, development, detachment, and the like being carried out on the surface of the semiconductor device 30 using a lithographic method, after which a groove portion 66ca that penetrates as far as the insulating layer 63 and the metal film 50c and extends approximately parallel to the X axis is formed by etching in the semiconductor device 30. Because of this, the barrier metal layer 51a, the conductive layer 51, and the barrier metal layer 51b extend approximately parallel to the X axis, and are divided into electrodes provided repeatedly in the Y axis +direction. This electrode corresponds to the bit line BL (refer to FIG. 1).

### Second Embodiment

A semiconductor device 30B according to a second embodiment will be described. From the second embodiment onward, a description of matters in common with the first embodiment will be omitted, and only differing points will be described. In particular, identical operational advantages resulting from identical configurations will not be referred to sequentially in each embodiment.

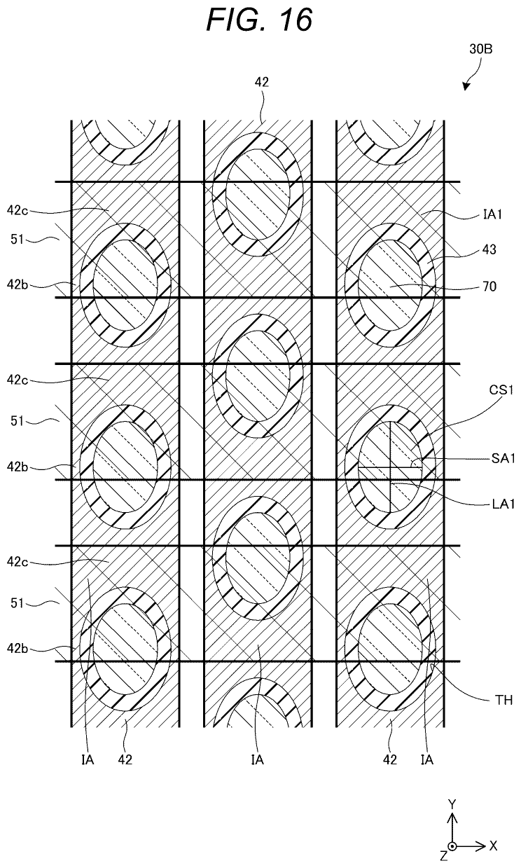

FIG. 16 is a drawing showing a cross-section of the semiconductor device 30B along the section line V-V shown in FIGS. 3 and 4. FIG. 16 is seen in the same way as FIG. 5.

As shown in FIG. 16, the semiconductor device 30B according to the second embodiment differs from the semiconductor device 30 according to the first embodiment in that the major axis LA1 in the cross-section CS1 of the oxide semiconductor layer 70 follows the Y axis direction. In the present embodiment, the major axis LA1 and the minor axis SA1 are approximately parallel to the Y axis and the X axis respectively.

Since a major axis of the cross-section CS1 follows the Y axis direction, that is, the direction in which the conductive layer 42 extends, as heretofore described, the width in the X axis direction of the conductive layer 42 can be reduced, while maintaining an area of the cross-section CS1 of the oxide semiconductor layer 70. Because of this, the multiple of conductive layers 42 can be disposed in close proximity to each other, meaning that a degree of integration of the semiconductor device 30B can be increased.

### Third Embodiment

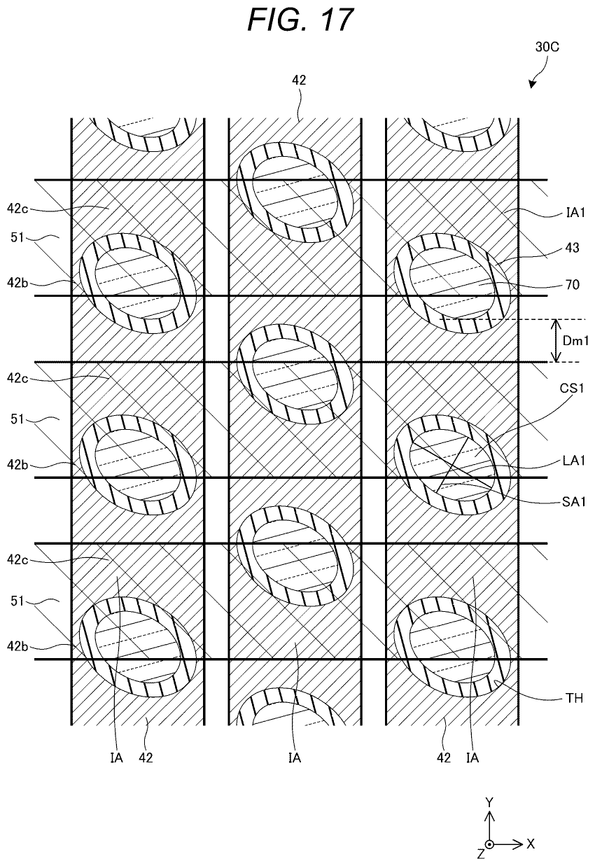

A semiconductor device 30C according to a third embodiment will be described. FIG. 17 is a drawing showing a cross-section of the semiconductor device 30C along the section line V-V shown in FIGS. 3 and 4. FIG. 17 is seen in the same way as FIG. 5.

As shown in FIG. 17, the semiconductor device 30C according to the third embodiment differs from the semiconductor device 30 according to the first embodiment in that the direction of the major axis LA1 in the cross-section CS1 of the oxide semiconductor layer 70 intersects the Y axis direction and the X axis direction. In the present embodiment, the direction of the major axis LA1 intersects the X axis direction at an angle of approximately 30°.

### Advantages

Since the direction of the major axis LA1 of the cross-section CS1 intersects the Y axis direction and the X axis direction, as heretofore described, the distance Dm1 can be secured, and the width in the X axis direction of the conductive layer 42 can be reduced, while maintaining the area of the cross-section CS1 of the oxide semiconductor layer 70. Because of this, an electrical short-circuiting of two neighboring conductive layers 51 via the upper electrode 50 due to production variation can be restricted. Also, the multiple of conductive layers 42 can be disposed in close proximity to each other, meaning that a degree of integration of the semiconductor device 30C can be increased.

### Fourth Embodiment

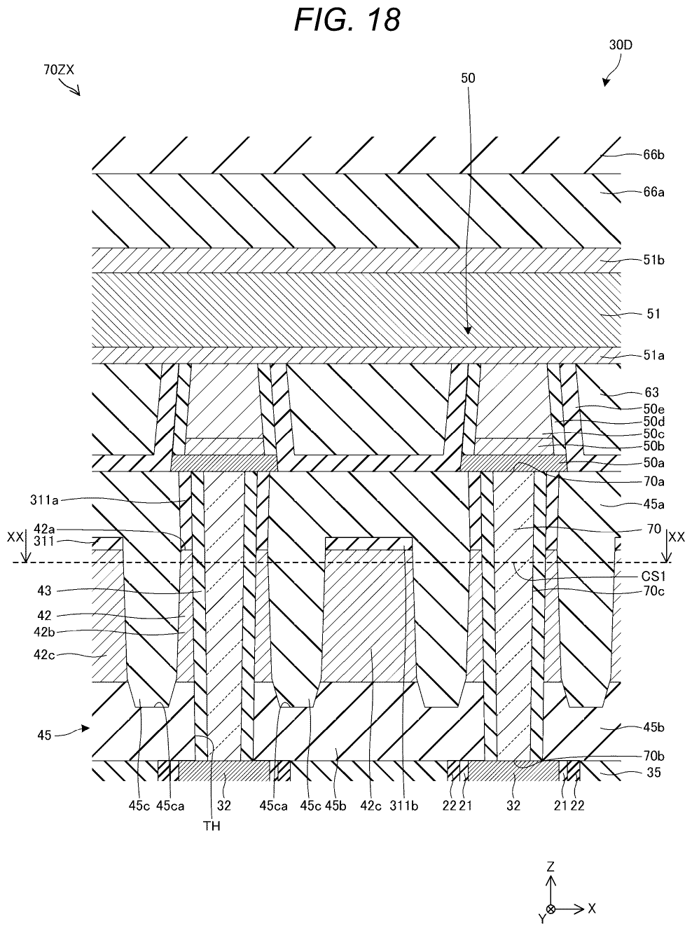

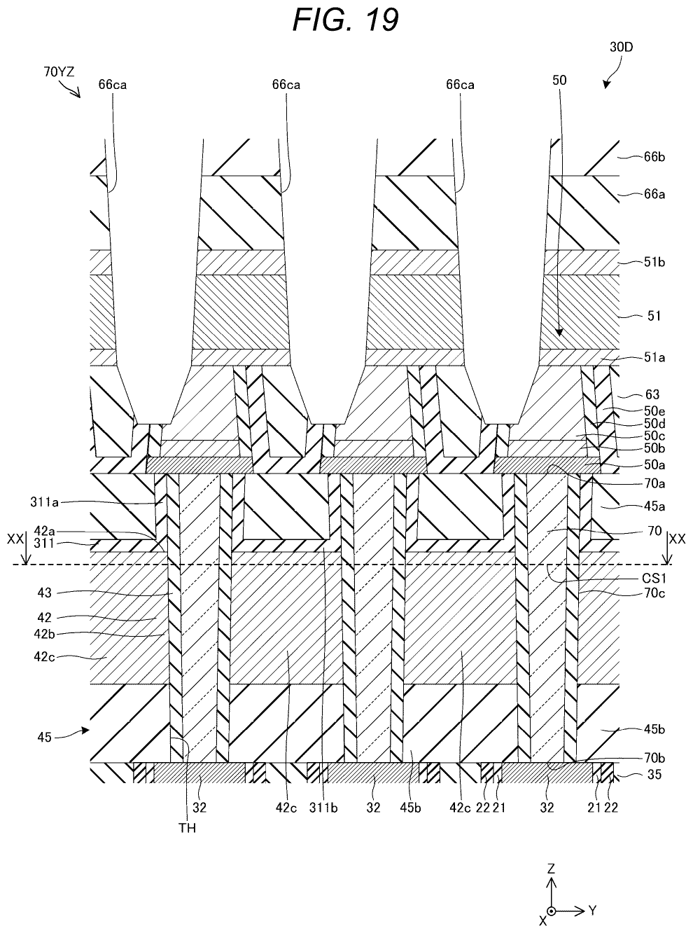

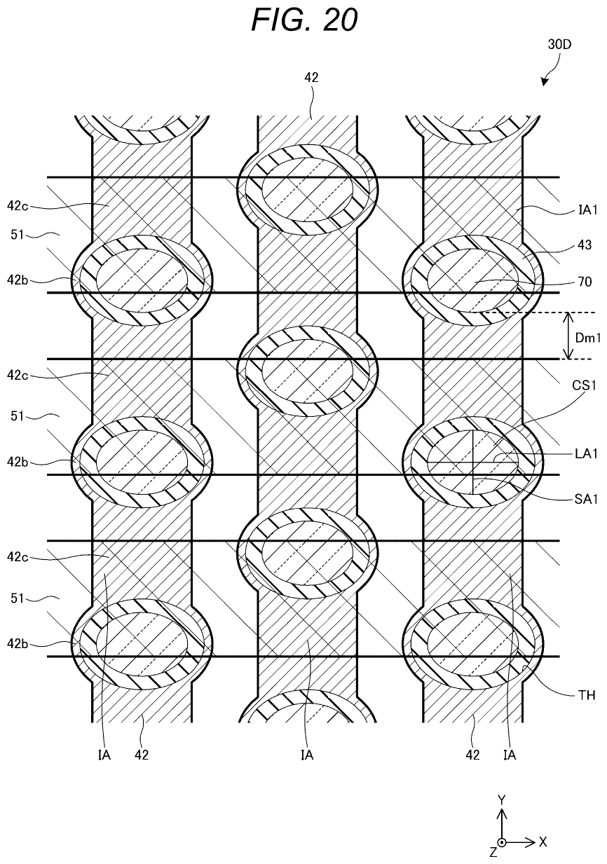

A semiconductor device 30D according to a fourth embodiment will be described. FIG. 18 is a detailed sectional view of the semiconductor device 30D when seen in a cross-section 70ZX in the oxide semiconductor layer 70, which is the cross-section 70ZX parallel to the ZX plane. FIG. 19 is a detailed sectional view of the semiconductor device 30D when seen in a cross-section 70YX in the oxide semiconductor layer 70, which is the cross-section 70YX parallel to the YX plane. FIG. 20 is a sectional view along a section line XX-XX shown in FIGS. 18 and 19.

As shown in FIGS. 18 to 20, the semiconductor device 30D according to the fourth embodiment differs from the semiconductor device 30 according to the first embodiment in that the enclosing portion 42b of the conductive layer 42 is formed by a self-alignment process.

Compared with the semiconductor device 30 shown in FIGS. 3 and 4, the semiconductor device 30D further includes a spacer film 311. The semiconductor device 30D is formed such that a width in the X axis direction of the linking portion 42c is smaller than a width in the X axis direction of the enclosing portion 42b.

In other words, when the conductive layer 42 is seen in the up-down direction, the width in the X axis direction of the conductive layer 42 decreases between two oxide semiconductor layers 70 neighboring in the Y axis direction.

The spacer film 311 is provided above the conductive layer 42. The spacer film 311 is, for example, an oxide of silicon. The spacer film 311 includes a cylindrical portion 311a and a plate-form portion 311b.

The cylindrical portion 311a is provided above the enclosing portion 42b of the conductive layer 42, and extends approximately parallel to the Z axis. Specifically, a lower end portion of the cylindrical portion 311a is an annular face that is in contact with an upper face 42a of the conductive layer 42. The cylindrical portion 311a encloses the oxide semiconductor layer 70 across the gate insulating film 43. The plate-form portion 311b is provided above the linking portion 42c of the conductive layer 42, and extends approximately parallel to the XY plane.

### Semiconductor Device 30D Manufacturing Method

Hereafter, a method of manufacturing the semiconductor device 30D according to the fourth embodiment will be described.

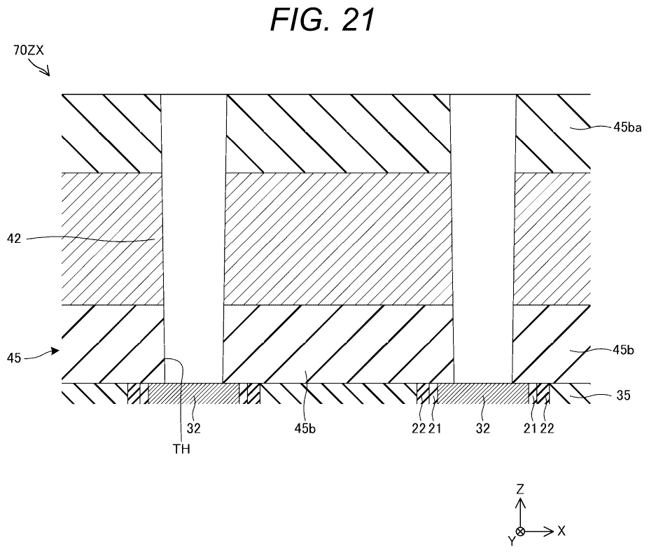

Firstly, as shown in FIG. 21, the insulating film 45b, the conductive layer 42, and an insulating film 45ba are stacked in that order above the lower electrode 32 and the insulating layer 35. The insulating film 45b, the conductive layer 42, and the insulating film 45ba extend approximately parallel to the XY plane. The transistor hole TH, which extends approximately parallel to the Z axis and penetrates the insulating film 45ba, the conductive layer 42, and the insulating film 45b, is formed, and subsequently cleaned. The lower electrode 32 is exposed in the bottom portion of the transistor hole TH. A cross-section vertical to the up-down direction of the transistor hole TH has an oval form.

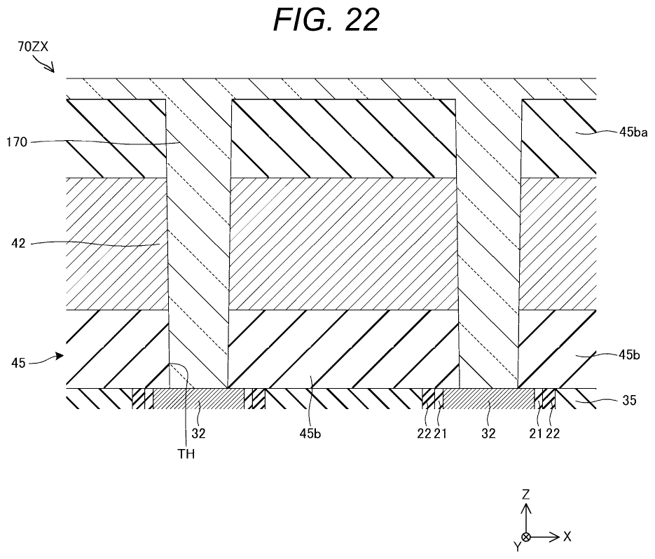

Next, as shown in FIG. 22, a sacrificial amorphous silicon layer 170 is formed on an upper face of the insulating film 45ba and in the transistor hole TH. Because of this, the transistor hole TH is filled with the sacrificial amorphous silicon layer 170.

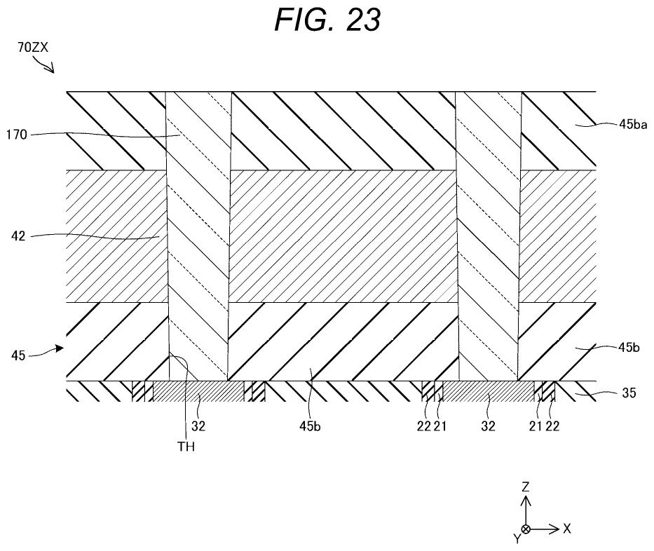

Next, as shown in FIG. 23, the sacrificial amorphous silicon layer 170 is etched back, whereby an upper portion of the sacrificial amorphous silicon layer 170 is removed, and the upper face of the insulating film 45ba is exposed. At this time, a position in the Z axis direction of a face of an upper end portion of the sacrificial amorphous silicon layer 170 is aligned with, for example, the upper face of the insulating film 45ba.

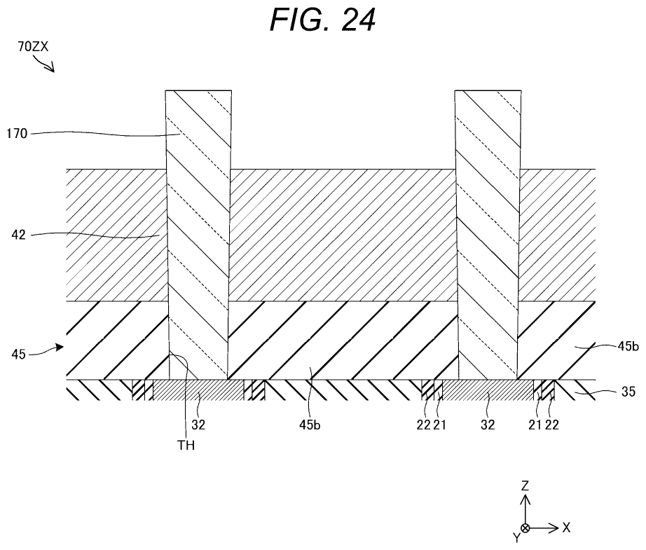

Next, as shown in FIG. 24, the insulating film 45ba is removed by being etched.

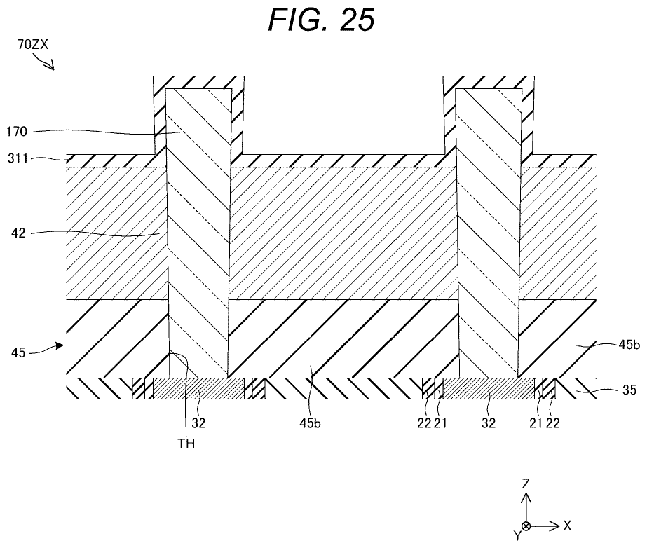

Next, as shown in FIG. 25, the spacer film 311, which covers the sacrificial amorphous silicon layer 170 exposed above the conductive layer 42 and the upper face of the conductive layer 42, is formed.

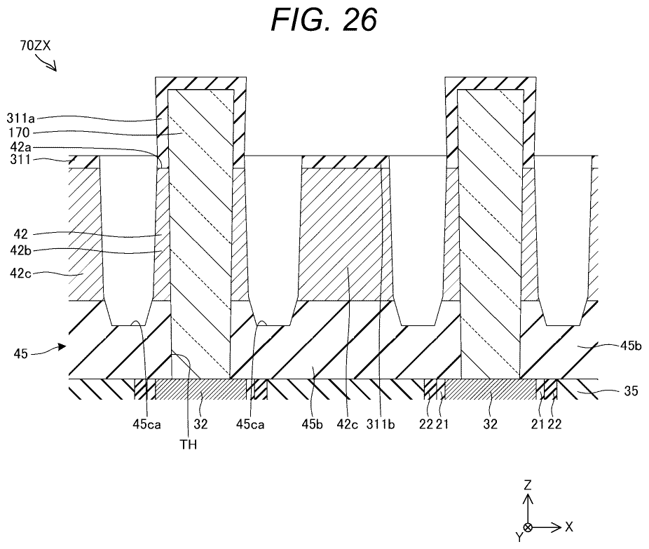

Next, as shown in FIG. 26, a mask is formed by a film formation, a resist application, exposure, development, detachment, and the like being carried out on an upper face of the spacer film 311 using a lithographic method, after which a groove portion 45ca that penetrates as far as the insulating film 45b and extends approximately parallel to the Y axis is formed by etching. Because of this, the spacer film 311 is divided into the cylindrical portion 311a and the plate-form portion 311b. Also, the conductive layer 42 is divided into a multiple of electrodes that extend approximately parallel to the Y axis and are provided repeatedly in the X axis +direction. This electrode corresponds to the word line WL (refer to FIG. 1).

The enclosing portion 42b of the conductive layer 42 is formed by a self-alignment process. Specifically, even when there is a deviation in a position in which a mask is formed using a lithographic method, the cylindrical portion 311a of the spacer film 311 positioned on a side face of the sacrificial amorphous silicon layer 170 functions as a mask, meaning that the enclosing portion 42b is formed by self-alignment in a periphery of the transistor hole TH.

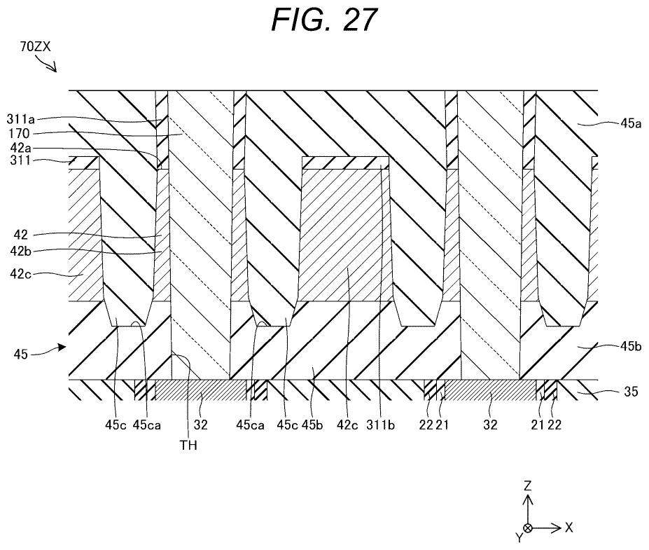

Next, as shown in FIG. 27, the insulating film 45c that fills the groove portion 45ca and the insulating film 45a provided above the spacer film 311 are formed integrated. Further, one portion of the insulating film 45a is removed by being subjected to a chemical mechanical polishing, whereby an upper face of the sacrificial amorphous silicon layer 170 is exposed in the insulating film 45a.

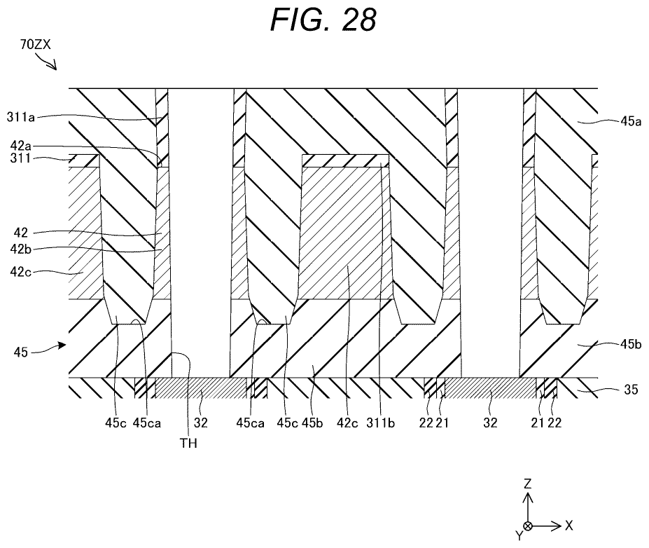

Next, as shown in FIG. 28, the sacrificial amorphous silicon layer 170 in the interior of the transistor hole TH is removed by etching.

As a subsequent manufacturing process is the same as in FIGS. 8 to 15, a detailed description will be omitted.

### Fifth Embodiment

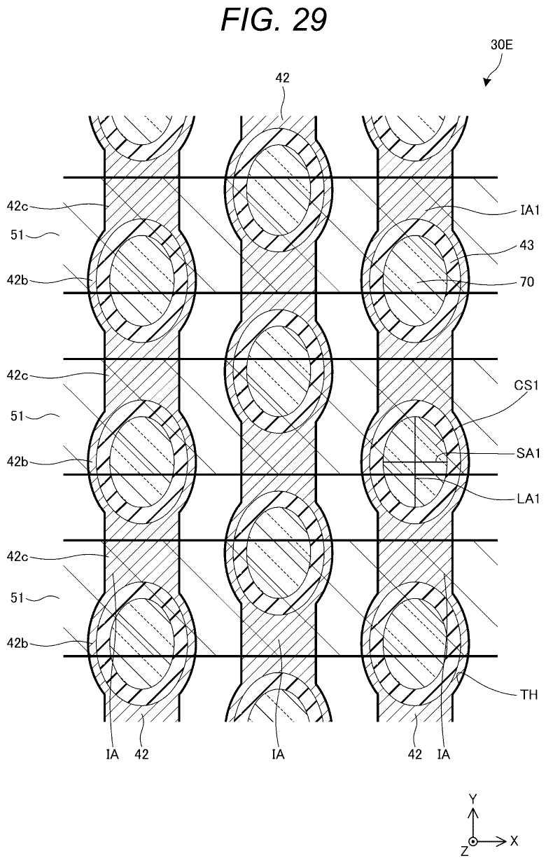

A semiconductor device 30E according to a fifth embodiment will be described. FIG. 29 is a drawing showing a cross-section of the semiconductor device 30E along the section line XX-XX shown in FIGS. 18 and 19. FIG. 29 is seen in the same way as FIG. 20.

As shown in FIG. 29, the semiconductor device 30E according to the fifth embodiment differs from the semiconductor device 30D according to the fourth embodiment in that the major axis LA1 in the cross-section CS1 of the oxide semiconductor layer 70 follows the Y axis direction. In the present embodiment, the major axis LA1 and the minor axis SA1 are approximately parallel to the Y axis and the X axis respectively.

### Sixth Embodiment

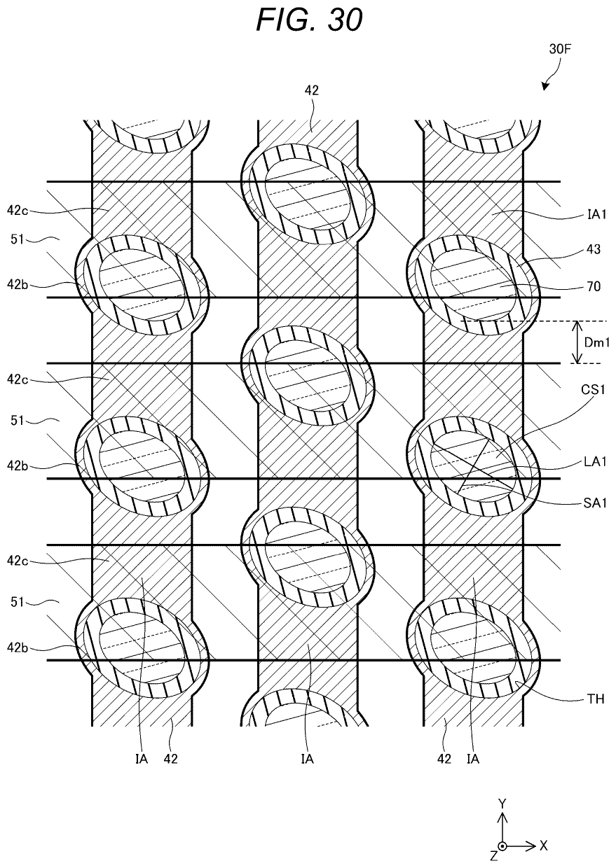

A semiconductor device 30F according to a sixth embodiment will be described. FIG. 30 is a drawing showing a cross-section of the semiconductor device 30F along the section line XX-XX shown in FIGS. 18 and 19. FIG. 30 is seen in the same way as FIG. 20.

As shown in FIG. 30, the semiconductor device 30F according to the sixth embodiment differs from the semiconductor device 30D according to the fourth embodiment in that the direction of the major axis LA1 in the cross-section CS1 of the oxide semiconductor layer 70 intersects the Y axis direction and the X axis direction. In the present embodiment, the direction of the major axis LA1 intersects the X axis direction at an angle of approximately 30°.

The cross-section CS1 vertical to the up-down direction of the oxide semiconductor layer 70 may be of a structure having a first length in the Y axis direction, and having a second length greater than the first length in the X axis direction, which intersects the up-down direction and the Y axis direction.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a plurality of gate electrodes that extend in a first direction and are separated from each other in a second direction intersecting the first direction;
a plurality of bit electrodes that extend in the second direction above the gate electrodes and are separated from each other in the first direction;
a plurality of oxide semiconductors that extend along a third direction intersecting the first and second directions, penetrate the gate electrodes, and are electrically connected to the gate electrodes and the bit electrodes; and
a plurality of gate insulating films each surrounding a corresponding one of the oxide semiconductors, wherein
within an intersection region in which one of the gate electrodes overlaps one of the bit electrodes in the third direction, said one of the gate electrodes opposes one of the oxide semiconductors across the gate insulating film, and
a cross-section of each of the oxide semiconductors taken along the first and second directions has an oval shape.

2. The semiconductor device according to claim 1, wherein
a major axis of the cross-section extends along the second direction.

3. The semiconductor device according to claim 1, wherein
a major axis of the cross-section extends along the first direction.

4. The semiconductor device according to claim 1, wherein
a major axis of the cross-section is 1.1 times or more greater than a minor axis of the cross-section.

5. The semiconductor device according to claim 1, wherein
the oxide semiconductors include a first oxide semiconductor and a second oxide semiconductor that is adjacent to the first oxide semiconductor in the second direction, and
when viewed from the third direction, the first oxide semiconductor is shifted in the first direction from the second oxide semiconductor.

6. The semiconductor device according to claim 5, wherein
the first and second oxide semiconductors are electrically connected to a first bit electrode, and
when viewed from the third direction, a part of the first oxide semiconductor is outside the first bit electrode on one side thereof in the first direction, and a part of the second oxide semiconductor is outside the first bit electrode on the other side thereof in the first direction.

7. The semiconductor device according to claim 1, wherein
each of the gate electrodes includes a plurality of enclosing portions that contact the gate insulating films and at least one linking portion that connects two of the enclosing portions, and
a width in the second direction of the linking portion is smaller than a width in the second direction of the enclosing portions.

8. The semiconductor device according to claim 1, wherein
a major axis of the cross section is inclined with respect to the first and second directions.

9. The semiconductor device according to claim 1, wherein
when viewed from the third direction, each of the gate electrodes is curved along an outer perimeter of the cross-section.

10. The semiconductor device according to claim 9, wherein
a major axis of the cross-section extends along the first direction.

11. The semiconductor device according to claim 9, wherein
a major axis of the cross section is inclined with respect to the first and second directions.

12. A semiconductor memory device, comprising:
a plurality of gate electrodes that extend in a first direction and are separated from each other in a second direction intersecting the first direction;
a plurality of bit electrodes that extend in the second direction above the gate electrodes and are separated from each other in the first direction;
a plurality of oxide semiconductors that extend along a third direction intersecting the first and second directions, penetrate the gate electrodes, and are electrically connected to the gate electrodes and the bit electrodes;
a plurality of gate insulating films each surrounding a corresponding one of the oxide semiconductors;
a plurality of first capacitor electrodes each electrically connected to a corresponding one of the oxide semiconductors;
a plurality of dielectric films each surrounding a corresponding one of the first capacitor electrodes; and
a plurality of second capacitor electrodes each surrounding a corresponding one of the dielectric films, wherein
within an intersection region in which one of the gate electrodes overlaps one of the bit electrodes in the third direction, said one of the gate electrodes opposes one of the oxide semiconductors across the gate insulating film, and
a cross section of each of the oxide semiconductors along the first and second directions has an oval shape.

13. The semiconductor memory device according to claim 12, wherein a major axis of the cross section extends along the second direction.

14. The semiconductor memory device according to claim 12, wherein
a major axis of the cross-section extends along the first direction.

15. The semiconductor memory device according to claim 12, wherein
a major axis of the cross-section is 1.1 times or more greater than a minor axis of the cross-section.

16. The semiconductor memory device according to claim 12, wherein
the oxide semiconductors include a first oxide semiconductor and a second oxide semiconductor that is adjacent to the first oxide semiconductor in the second direction, and
when viewed from the third direction, the first oxide semiconductor is shifted in the first direction from the second oxide semiconductor.

17. The semiconductor memory device according to claim 16, wherein
the first and second oxide semiconductors are electrically connected to a first bit electrode, and
when viewed from the third direction, a part of the first oxide semiconductor is outside the first bit electrode on one side thereof in the first direction, and a part of the second oxide semiconductor is outside the first bit electrode on the other side thereof in the first direction.

18. The semiconductor memory device according to claim 12, wherein
each of the gate electrodes includes a plurality of enclosing portions that contact the gate insulating films and at least one linking portion that connects two of the enclosing portions, and
a width in the second direction of the linking portion is smaller than a width in the second direction of the enclosing portions.

19. The semiconductor memory device according to claim 12, wherein
a major axis of the cross section is inclined with respect to the first and second directions.

20. The semiconductor memory device according to claim 12, wherein
when viewed from the third direction, each of the gate electrodes is curved along an outer perimeter of the cross-section.
